(19) United States
(12) Patent Application Publication
(10) Pub. No.: US 2026/0239961 A1
(43) Pub. Date: Aug. 13, 2026

(54) METHOD OF MANUFACTURING SEMICONDUCTOR DEVICE AND SEMICONDUCTOR DEVICE

(71) Applicant: Mitsubishi Electric Corporation, Tokyo (JP)

(72) Inventors: Takuya SHIRATSURU, Tokyo (JP); Yuki YANO, Tokyo (JP)

(73) Assignee: Mitsubishi Electric Corporation, Tokyo (JP)

(21) Appl. No.: 19/148,226

(22) PCT Filed: Mar. 30, 2023
(86) PCT No.: PCT/JP2023/013082

§ 371 Date: Jul. 15, 2025

(51) Int. Cl. H10W 40/22; H10W 40/00; H10W 40/20; H10W 40/25

(52) U.S. Cl. CPC H10W 40/226; H10W 40/037; H10W 40/235; H10W 40/255

(57) ABSTRACT

Provided is a method of manufacturing a semiconductor device improving reliability of a semiconductor device including a cooling fin. A method of manufacturing a semiconductor device includes: a step of preparing a base plate holding a semiconductor element; and a step of attaching a cooling fin to a back surface of the base plate. The step of attaching the cooling fin includes a step of forming a bonding part in which the base plate and the cooling fin are bonded by welding. The bonding part is formed in a region other than a region immediately below the semiconductor element.

### TECHNICAL FIELD

The present disclosure relates to a method of manufacturing a semiconductor device and a semiconductor device.

### BACKGROUND ART

A semiconductor device includes a cooling fin for radiating heat generated in a semiconductor element in the semiconductor device to an outer part. For example, Patent Document 1 discloses a semiconductor device in which a cooling fin such as a flat fin or a corrugated fin is provided.

### PRIOR ART DOCUMENTS

### Patent Document(s)

Patent Document 1: International Publication No. 2020/157965

### SUMMARY

### Problem to be Solved by the Invention

When the cooling fin is bonded to a metal base plate holding the semiconductor element by a bonding material, a bonding part is heated to have a temperature equal to or larger than a melting point of the bonding material. An inner part of the semiconductor device is also heated in a heating process. The heat has influence on components constituting the semiconductor device and bonding parts thereof. As a result, reliability of the semiconductor device such as a lifetime thereof is reduced.

In order to solve the above problems, an object of the present disclosure is to provide a method of manufacturing a semiconductor device improving reliability of a semiconductor device including a cooling fin.

### Means to Solve the Problem

A method of manufacturing a semiconductor device according to the present disclosure includes: a step of preparing a base plate holding a semiconductor element; and a step of attaching a cooling fin to a back surface of the base plate. The step of attaching the cooling fin includes a step of forming a bonding part in which the base plate and the cooling fin are bonded by welding. The bonding part is formed in a region other than a region immediately below the semiconductor element.

### Effects of the Invention

According to the present disclosure, provided is a method of manufacturing a semiconductor device improving reliability of a semiconductor device including a cooling fin.

These and other objects, features, aspects and advantages of the present disclosure will become more apparent from the following detailed description of the present disclosure when taken in conjunction with the accompanying diagrams.

### BRIEF DESCRIPTION OF DRAWINGS

FIG. 1 is a cross-sectional view illustrating a schematic configuration of a semiconductor device according to an embodiment 1.

FIG. 2 is a plan view illustrating a configuration of a back surface of the semiconductor device.

FIG. 3 is a flow chart illustrating a method of manufacturing the semiconductor device according to the embodiment 1.

FIG. 4 is a cross-sectional view illustrating a configuration of the semiconductor device in a manufacturing process.

FIG. 5 is a cross-sectional view illustrating a configuration of the semiconductor device in the manufacturing process.

FIG. 6 is a cross-sectional view illustrating a configuration of the semiconductor device in the manufacturing process.

FIG. 7 is a cross-sectional view illustrating a configuration of the semiconductor device in the manufacturing process.

FIG. 8 is a cross-sectional view illustrating a schematic configuration of a semiconductor device according to an embodiment 2.

FIG. 9 is a plan view illustrating a configuration of a back surface of a semiconductor device according to an embodiment 3.

FIG. 10 is a cross-sectional view illustrating a schematic configuration of a semiconductor device according to an embodiment 4.

FIG. 11 is a cross-sectional view illustrating a schematic configuration of a semiconductor device according to an embodiment 5.

### DESCRIPTION OF EMBODIMENT(S)

### Embodiment 1

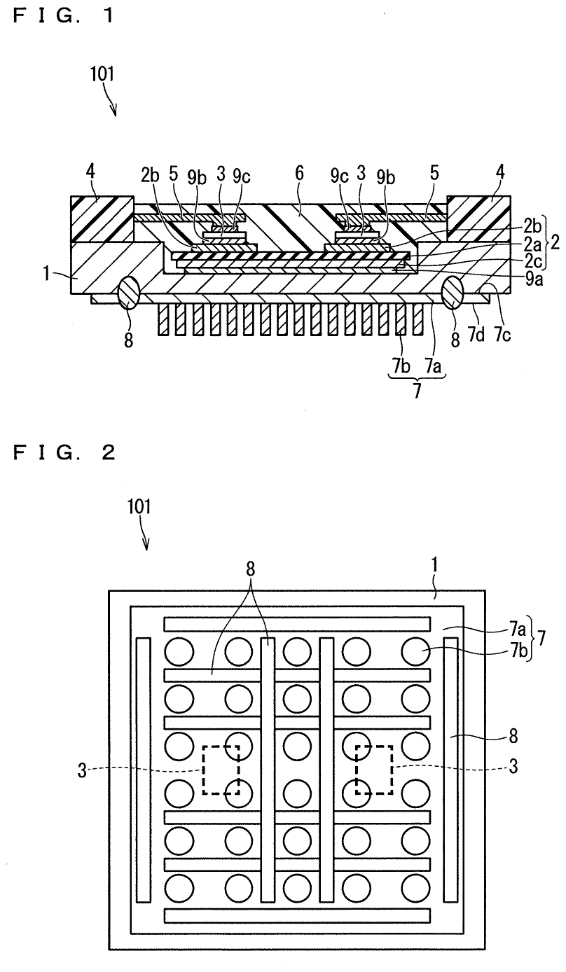

FIG. 1 is a cross-sectional view illustrating a schematic configuration of a semiconductor device 101 according to an embodiment 1. FIG. 2 is a plan view illustrating a configuration of a back surface of the semiconductor device 101.

The semiconductor device 101 includes a base plate 1, an insulating substrate 2, a semiconductor element 3, a case 4, a lead 5, a sealing material 6, a cooling fin 7, and a bonding part 8. In FIG. 1 and FIG. 2, a configuration of the semiconductor device 101 is illustrated in a simplified form. For example, illustration of a metal wire and a signal terminal electrically connected to the semiconductor element 3 is omitted.

The base plate 1 is formed by a material excellent in heat conductivity. The base plate 1 is a metal plate formed of aluminum or copper, for example. Although the detailed configuration is described hereinafter, the base plate 1 holds the insulating substrate 2 and the semiconductor element 3. The base plate 1 transmits heat generated in an electrical component such as the semiconductor element 3 to an outer part.

The insulating substrate 2 is held on a surface of the base plate 1. The insulating substrate 2 includes an insulating layer 2a, a front surface conductive pattern 2b, and a back surface conductive pattern 2c. The insulating substrate 2 includes the insulating layer 2a, thereby functioning as an insulating member. The insulating layer 2a is formed of a material excellent in heat conductivity. The insulating layer 2a is formed of ceramic or resin, for example. Ceramic is aluminum nitride or silicon nitride, for example. The front surface conductive pattern 2b is provided on an upper surface of the insulating layer 2a. The back surface conductive pattern 2c is provided on a lower surface of the insulating layer 2a. The front surface conductive pattern 2b and the back surface conductive pattern 2c are formed of a material excellent in thermal conductivity and electrical conductivity. The front surface conductive pattern 2b and the back surface conductive pattern 2c are formed of metal such as aluminum or copper, for example. The back surface conductive pattern 2c is bonded to the base plate 1 via a bonding material 9a. The bonding material 9a is soft wax such as solder, for example.

The semiconductor element 3 is bonded to the front surface conductive pattern 2b of the insulating substrate 2 via the bonding material 9b. The bonding material 9b has conductivity. The bonding material 9b is soft wax such as solder, for example. The semiconductor element 3 according to the embodiment 1 is a vertical semiconductor element in which current flows between the upper surface and the lower surface thereof. The semiconductor element 3 is formed of Si, for example. The semiconductor element 3 is formed of semiconductor such as SiC, GaN, Ga₂O₃, or diamond having larger bandgap than Si, for example. The semiconductor element 3 is a power semiconductor element or a control integrated circuit (IC) for controlling the power semiconductor element, for example. The semiconductor element 3 includes an insulated gate bipolar transistor (IGBT), a metal oxide semiconductor field effect transistor (MOSFET), or a Schottky barrier diode, for example. The semiconductor element 3 may include a reverse-conducting IGBT in which an IGBT and a reflux diode are formed in one semiconductor substrate. Although two semiconductor elements 3 are mounted to the insulating substrate 2 in FIG. 1, the number of the mounted semiconductor elements 3 is not limited. A necessary number of semiconductor elements 3 are mounted to the insulating substrate 2 as usage of the semiconductor device 101.

The case 4 is provided on the base plate 1. The case 4 may be bonded to the base plate 1 by an adhesive material such as silicone or may also be fastened to the base plate 1 with a screw. Although illustration is omitted, the case 4 includes a rectangular frame body in a plan view. The case 4 houses the insulating substrate 2 and the semiconductor element 3 inside the frame body. The case 4 is formed of resin having high heat resistance properties. The resin is polyphenylene sulfide (PPS) or polybutylene terephthalate (PBT), for example.

The lead 5 is a conductor which can be connected to an external circuit (not shown) provided to an outer part of the semiconductor device 101. The lead 5 is formed of a material such as copper, for example, excellent in electrical conductivity. The lead 5 is a metal frame in which a metal plate is processed to have a predetermined shape. The lead 5 is a component integrally formed with the case 4, for example. When the lead 5 is integrally formed with the case 4, a part of the lead 5 is embedded into the case 4 and fixed thereto. The lead 5 and the case 4 having such configurations are manufactured by insert molding. One end of the lead 5 is bonded to the front surface conductive pattern 2b of the insulating substrate 2 or the semiconductor element 3. One end of the lead 5 in the embodiment 1 is bonded to the upper surface of the semiconductor element 3 by the bonding material 9c. The bonding material 9c has conductivity. The bonding material 9c is soft wax such as solder, for example. The other end (not shown) of the lead 5 is led to an outer part of the case 4, and can be connected to an external circuit. The lead 5 has functions as an internal wiring, a terminal, and an electrode in the semiconductor device 101, for example.

The sealing material 6 fills a space inside the case 4. The sealing material 6 seals the front surface of the base plate 1, the insulating substrate 2, the semiconductor element 3, and the lead 5. The sealing material 6 is formed of resin having insulation properties and hardenability. The sealing material 6 is formed of silicone gel or epoxy resin, for example.

The cooling fin 7 is attached to the back surface of the base plate 1. The cooling fin 7 includes a flat plate part 7a and a fin part 7b. The flat plate part 7a includes a mounting surface 7c facing the back surface of the base plate 1 and a heat radiation surface 7d on a side opposite to the mounting surface 7c. The fin part 7b includes a plurality of fins provided upright on the heat radiation surface 7d. The fin in the embodiment 1 is a pin fin. The fin part 7b may have a structure that a plurality of straight plates are provided upright or a structure that one thin plate is bended at intervals as a plurality of fins. The cooling fin 7 is formed of aluminum or copper, for example. The cooling fin 7 is manufactured by extrusion molding, molding, forging, cutting work, or bending work, for example.

The bonding part 8 bonds the base plate 1 and the cooling fin 7. The bonding part 8 is provided in a region other than a region immediately below the semiconductor element 3. The bonding part 8 in the embodiment 1 is provided between the plurality of fins in the fin parts 7b and is also provided to the flat plate part 7a outside the fin part 7b as illustrated in FIG. 2.

The bonding part 8 directly bonds the base plate 1 and the flat plate part 7a of the cooling fin 7. In other words, a bonding material, for example, is not provided between the base plate 1 and the flat plate part 7a of the cooling fin 7 in the bonding part 8.

The bonding part 8 includes a welding mark. The welding mark in the bonding part 8 includes a material in which a material of the base plate 1 and a material of the cooling fin 7 are combined with each other. The welding mark in the surface of the bonding part 8 includes a mark formed in the heat radiation surface 7d of the flat plate part 7a and made by melting the material of the cooling fin 7.

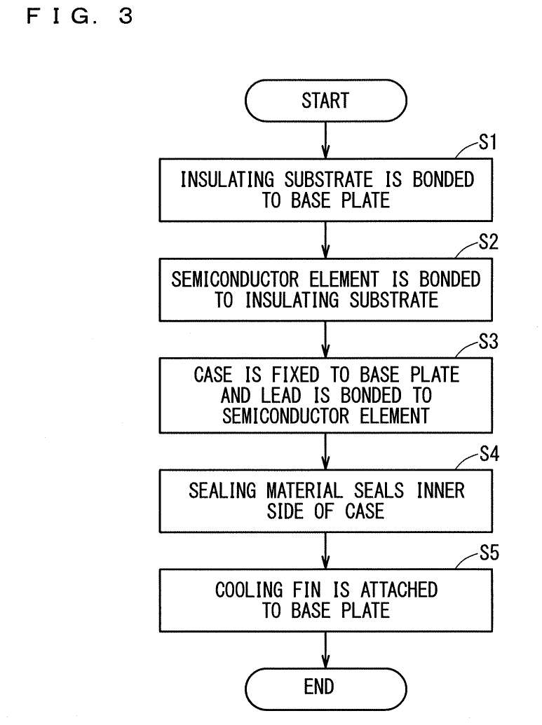

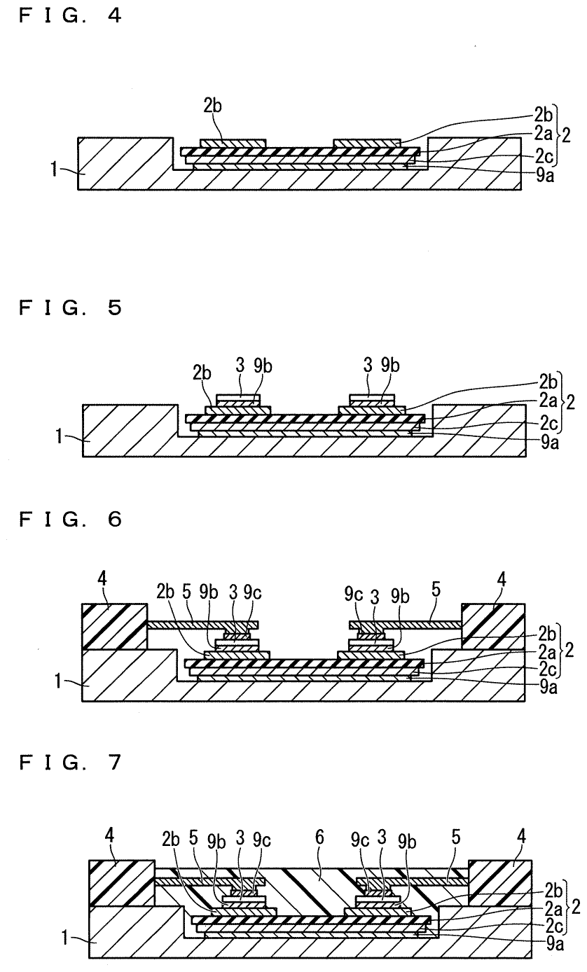

FIG. 3 is a flow chart illustrating a method of manufacturing the semiconductor device 101 according to the embodiment 1. FIG. 4 to FIG. 7 are cross-sectional views each illustrating a configuration of the semiconductor device 101 in a manufacturing process.

In Step S1, as illustrated in FIG. 4, the insulating substrate 2 is bonded to the front surface of the base plate 1 by the bonding material 9a. In this process, the paste-like bonding material 9a is supplied to the front surface of the base plate 1. For example, the bonding material 9a including an activator such as flux is applied to the front surface of the base plate 1. The bonding material 9a is soft wax such as solder, for example. The bonding material 9a may be supplied by screen printing. A bonding material previously molded to have a sheet-like shape may be disposed on the front surface of the base plate 1 in place of the paste-like bonding material 9a. The insulating substrate 2 is disposed on the bonding material 9a. The bonding material 9a is melted by heating at a temperature exceeding a melting point of the bonding material 9a. Accordingly, the back surface conductive pattern 2c of the insulating substrate 2 is bonded to the base plate 1 via the bonding material 9a.

In Step S2, as illustrated in FIG. 5, the semiconductor element 3 is bonded to the front surface conductive pattern 2b of the insulating substrate 2 by the bonding material 9b. In this process, the bonding material 9b is supplied to the front surface conductive pattern 2b of the insulating substrate 2. The semiconductor element 3 is disposed on the bonding material 9b. The bonding material 9b is melted by heating at a temperature exceeding a melting point of the bonding material 9b. Accordingly, the lower surface of the semiconductor element 3 is bonded to the front surface conductive pattern 2b of the insulating substrate 2 via the bonding material 9b. The process in Steps S1 and S2 described above corresponds to the process of preparing the base plate 1 holding the semiconductor element 3.

In Step S3, as illustrated in FIG. 6, the case 4 is fixed on the base plate 1, and the lead 5 is bonded to the semiconductor element 3. Herein, the case 4 is manufactured by insert molding, and is integrally formed with the lead 5. That is to say, a part of the lead 5 is embedded into the case 4. In this process, an adhesive material (not shown) is applied on the base plate 1, and the case 4 is disposed on the adhesive material, for example. At this time, a part of the case 4 may be fitted to the base plate 1. The adhesive material is hardened by heating. The case 4 may be fixed to the base plate 1 by fastening with a screw.

The bonding material 9c is supplied to the upper surface of the semiconductor element 3. One end of the lead 5 is disposed on the bonding material 9c. The bonding material 9c is melted by heating at a temperature exceeding a melting point of the bonding material 9c. Accordingly, one end of the lead 5 is bonded to the upper surface of the semiconductor element 3 via the bonding material 9c. A lead such as an aluminum wire may be bonded to the upper surface of the semiconductor element 3 by ultrasonic bonding in place of the lead 5 formed of a metal plate.

In Step S4, an inner side of the case 4 is sealed with the sealing material 6 as illustrated in FIG. 7. In this process, a liquid sealing material 6 firstly fills the case 4. Subsequently, the base plate 1 and the case 4 are put in a curing furnace and heated. The sealing material 6 is thereby hardened.

In Step S5, as illustrated in FIG. 1, the cooling fin 7 is attached to the back surface of the base plate 1. At that time, formed is the bonding part 8 in which the base plate 1 and the cooling fin 7 are bonded by welding. In the embodiment 1, the cooling fin 7 is bonded to the base plate 1 by laser welding. In the laser welding, a welding position is irradiated with high-power laser light, and metal of the cooling fin 7 and metal of the base plate 1 are locally melted. Accordingly, the metal of the cooling fin 7 is melted into the metal of the base plate 1. The metal of the cooling fin 7 and the metal of the base plate 1 are mixed into each other. A melting depth thereof is controlled so as to pass through the cooling fin 7 but not to pass through the base plate 1. The base plate 1 and the cooling fin 7 are bonded to each other to form the bonding part 8 by such a through welding. The base plate 1 and the cooling fin 7 are directly bonded to each other in the bonding part 8. The welding mark is formed in the bonding part 8.

The laser welding is performed at a position away from a position to which the semiconductor element 3 is mounted. That is to say, the bonding part 8 is formed in a region other than a region immediately below the semiconductor element 3. The bonding part 8 in the embodiment 1 is formed between the plurality of fins and is also formed in the flat plate part 7a outside the fin part 7b. Laser easily outputting high power is used for welding. For example, a fiber layer is formed. Also applicable is short-wavelength laser light having a high absorbing ratio with respect to a material constituting the cooling fin 7 and the base plate 1. For example, blue laser or green laser is used for metal such as copper.

A welding state of the bonding part 8 is inspected by an ultrasonic testing or an X-ray diagnosis, for example. After Step S5, a necessary inspection of electrical properties, for example, is executed, and the semiconductor device 101 is completed.

To sum up the above, the method of manufacturing the semiconductor device 101 according to the embodiment 1 includes the process of preparing the base plate 1 holding the semiconductor element 3 and the process of attaching the cooling fin 7 to the back surface of the base plate 1. The process of attaching the cooling fin 7 includes the process of forming the bonding part 8 in which the base plate 1 and the cooling fin 7 are bonded by welding. The bonding part 8 is formed in the region other than the region immediately below the semiconductor element 3.

The laser welding is a thermal bonding method locally performed in a short time. Heat energy in welding inputted to the bonding part 8 is instantaneously diffused to the cooling fin 7 and the base plate 1. Influence of heat in welding on the components constituting the semiconductor device 101 is reduced. The welding in the embodiment 1 is performed in the region other than the region immediately below the semiconductor element 3. The heat in welding is hardly transmitted to the bonding material 9b provided immediately below the semiconductor element 3. Increase in size of the metallic structure does not occur or is reduced. Thus, reduction of a lifetime of the bonding material 9b is suppressed. The method of manufacturing the semiconductor device 101 in the embodiment 1 improves reliability of the semiconductor device 101 including the cooling fin 7.

Although laser welding is preferable as the method of welding the base plate 1 and the cooling fin 7, the method thereof is not limited thereto. Various welding methods can be adopted.

The insulating substrate 2 as the insulating member in the embodiment 1 is held by the base plate 1 via the bonding material 9a, and is a component different from the base plate 1. The insulating member may be one component (not shown) integrally formed with the base plate 1 in place of the insulating substrate 2. For example, the insulating member may be an insulating layer formed on the base plate 1 and a surface conductive pattern formed on the insulating layer. In this case, the bonding material 9a is not located between the insulating member and the base plate 1. The insulating layer is formed of resin, for example.

### Embodiment 2

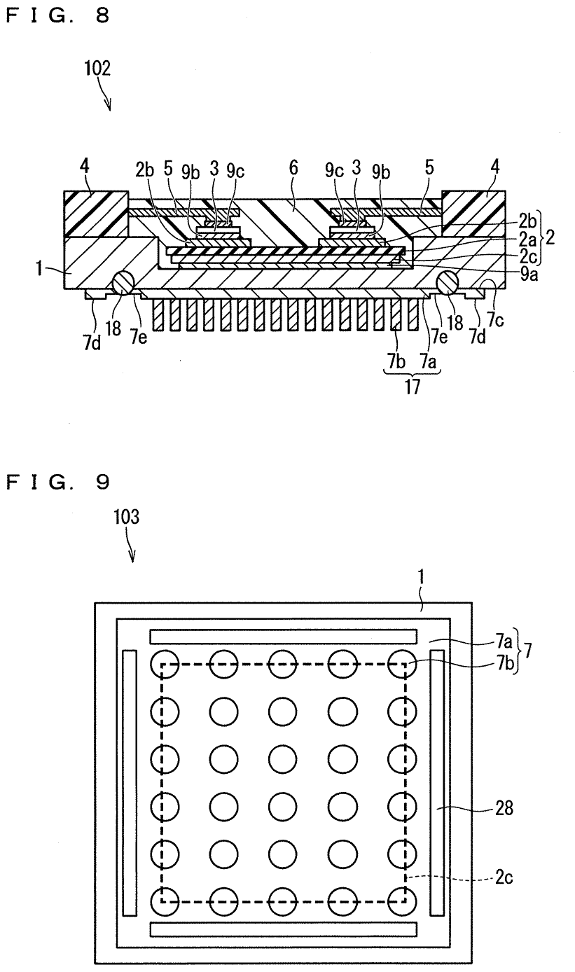

In an embodiment 2, the same reference numerals are assigned to constituent elements similar to those in the embodiment 1, and the detailed description thereof is omitted. FIG. 8 is a cross-sectional view illustrating a schematic configuration of a semiconductor device 102 according to the embodiment 2. The semiconductor device 102 includes a cooling fin 17 and a bonding part 18.

The cooling fin 17 includes a concave part 7e provided to the hear radiation surface 7d of the flat plate part 7a in addition to the flat plate part 7a and the fin part 7b. The concave part 7e is disposed in a part of the heat radiation surface 7d in which the fin part 7b is not provided. The concave part 7e in the embodiment 2 is provided to an outer surrounding of the fin part 7b. The concave part 7e is provided in a region other than a region immediately below the semiconductor element 3.

The bonding part 18 is provided to the concave part 7e. A welding mark of the bonding part 18 is formed in the concave part 7e. A top part of the welding mark in the concave part 7e is lower than the heat radiation surface 7d around the concave part 7e. That is to say, the top part of the welding mark does not protrude more than the heat radiation surface 7d around the concave part 7e. The other configuration is similar to that of the embodiment 1.

In Step S5 illustrated in FIG. 3, the bonding part 18 is formed in the concave part 7e. When the cooling fin 17 is welded to the base plate 1, the concave part 7e is irradiated with laser. Accordingly, metal of the concave part 7e of the cooling fin 17 is melted into the metal of the base plate 1. The metal of the cooling fin 17 and the metal of the base plate 1 are mixed into each other. A melting depth thereof is controlled so as to pass through the concave part 7e of the cooling fin 17 but not to pass through the base plate 1. The bonding part 18 in which the base plate 1 and the cooling fin 17 are bonded to each other is formed by such a through welding. The welding mark of the bonding part 18 is formed in the concave part 7e. A welding state of the bonding part 18 is inspected by an ultrasonic testing or an X-ray diagnosis, for example.

The welding mark is formed when the melted metal is solidified. Thus, a height of a surface of the welding mark has some degree of variability. The variability of the height of the welding mark depends on a condition of laser irradiation and a state of an irradiation target. For example, when two copper plates having a thickness of 1.5 mm is through-welded by a fiber laser, variability of a height of a welding mark is approximately equal to or smaller than 0.5 mm.

When the semiconductor device 102 is used, a cooling medium flows on the heat radiation surface 7d of the cooling fin 17, and thermal exchange is performed. When the height of the welding mark has variability, sealing properties of the cooling medium on the heat radiation surface 7d is deteriorated. When welding is performed so that the welding mark is formed in the concave part 7e, the semiconductor device 102 can be used while sealing properties of the cooling medium is not deteriorated due to variability of a shape of the welding mark.

### Embodiment 3

In an embodiment 3, the same reference numerals are assigned to constituent elements similar to those in the embodiment 1 or 2, and the detailed description thereof is omitted. FIG. 9 is a plan view illustrating a configuration of a back surface of a semiconductor device 103 according to the embodiment 3. The semiconductor device 103 includes a bonding part 28. Configurations other than the bonding part 28 are similar to those of the embodiment 1 or 2.

The bonding part 28 bonds the base plate 1 and the cooling fin 7. The bonding part 28 is provided in a region other than a region immediately below the back surface conductive pattern 2c. The region in which the bonding part 28 is provided is also the region other than the region immediately below the semiconductor element 3.

In Step S5 illustrated in FIG. 3, the bonding part 28 is formed by laser welding. The bonding part 28 is formed in the region other than the region immediately below the back surface conductive pattern 2c. In this process, the region other than the region immediately below the back surface conductive pattern 2c is irradiated with the laser. The metal of the cooling fin 7 is melted into the metal of the base plate 1. The metal of the cooling fin 7 and the metal of the base plate 1 are mixed into each other. The bonding part 28 in which the base plate 1 and the cooling fin 7 are bonded to each other is formed by such a through welding. A welding state of the bonding part 28 is inspected by an ultrasonic testing or an X-ray diagnosis, for example.

The welding in the embodiment 3 is performed in the region other than the region immediately below the back surface conductive pattern 2c. Heat in welding is hardly transmitted to the bonding material 9a immediately below the back surface conductive pattern 2c. Increase in size of the metallic structure does not occur or is reduced. Thus, reduction of a lifetime of the bonding material 9a is suppressed. The method of manufacturing the semiconductor device 103 in the embodiment 3 improves reliability of the semiconductor device 103.

### Embodiment 4

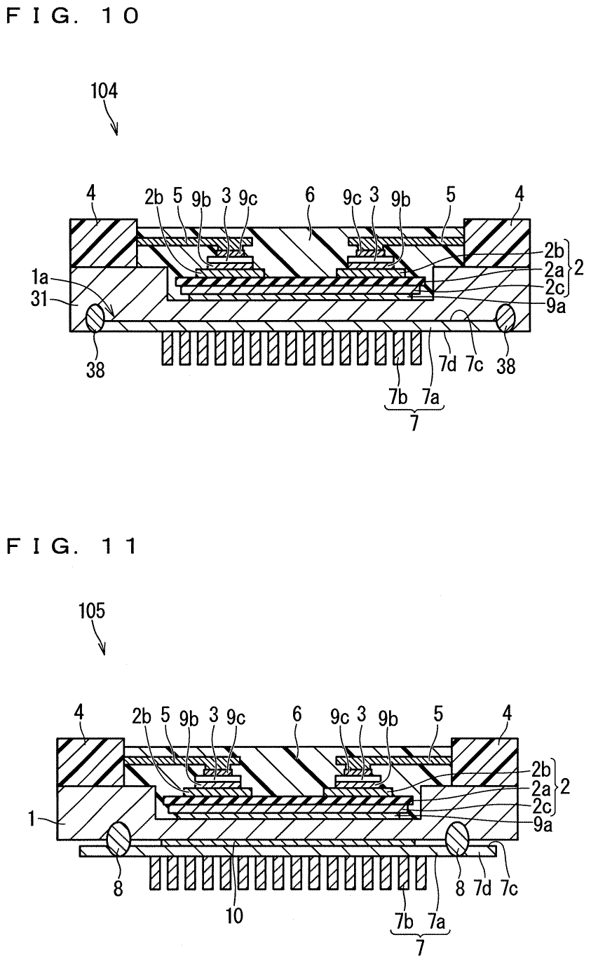

In an embodiment 4, the same reference numerals are assigned to constituent elements similar to those in any of the embodiments 1 to 3, and the detailed description thereof is omitted. FIG. 10 is a cross-sectional view illustrating a schematic configuration of a semiconductor device 104 according to the embodiment 4. The semiconductor device 104 includes a base plate 31 and a bonding part 38.

The base plate 31 includes a fitting part 1a to which a part of the cooling fin 7 is fitted on a back surface thereof. The fitting part 1a in the embodiment 4 has a shape so that the flat plate part 7a of the cooling fin 7 is fitted to the fitting part 1a. The cooling fin 7 is provided so that the flat plate part 7a is fitted to the fitting part 1a. The other configuration is similar to that of any one of the embodiments 1 to 3.

The bonding part 38 bonds a region including a gap between a side surface of the fitting part 1a and a side surface of the flat plate part 7a fitted to the fitting part 1a. The side surface of the fitting part 1a of the base plate 31 and the side surface of the flat plate part 7a of the cooling fin 7 are directly bonded to each other in the bonding part 38. A welding mark of the bonding part 38 is formed in the region including the side surface of the fitting part 1a of the base plate 31 and the side surface of the flat plate part 7a of the cooling fin 7.

In Step S5 illustrated in FIG. 3, the flat plate part 7a of the cooling fin 7 is firstly fitted to the fitting part 1a. Next, the bonding part 38 is formed by laser welding. The bonding part 38 bonds the side surface of the fitting part 1a and the side surface of the flat plate part 7a fitted to the fitting part 1a. When the cooling fin 7 is welded to the base plate 31, the region including the gap between the side surface of the fitting part 1a and the side surface of the flat plate part 7a is irradiated with laser. The metal of the cooling fin 7 is melted into the metal of the base plate 31. The metal of the cooling fin 7 and the metal of the base plate 31 are mixed into each other. The bonding part 38 is formed by such a gap welding.

Since the bonding part 38 is formed in the gap between the base plate 31 and the cooling fin 7, applicable to an inspection of a welding state thereof is an inspection by an ultrasonic testing or an X-ray diagnosis and a visual appearance inspection. Thus, the inspection is easily performed.

### Embodiment 5

In an embodiment 5, the same reference numerals are assigned to constituent elements similar to those in any of the embodiments 1 to 3, and the detailed description thereof is omitted. FIG. 11 is a cross-sectional view illustrating a schematic configuration of a semiconductor device 105 according to an embodiment 5. The semiconductor device 105 includes a heat conductive material 10. The other configuration is similar to that of any one of the embodiments 1 to 3.

The heat conductive material 10 is provided between the base plate 1 and the cooling fin 7. The heat conductive material 10 is disposed in a position in which the bonding part 8 is not provided. The heat conductive material 10 is a viscous material into which metal particles are mixed. The heat conductive material 10 is a silicone grease, for example.

In Step S5 illustrated in FIG. 3, the heat conductive material 10 is applied or printed between the base plate 1 and the cooling fin 7. When a region away from the region in which the heat conductive material 10 is provided is irradiated with laser, the cooling fin 7 and the base plate 1 are welded to each other.

Since the heat conductive material 10 is provided between the base plate 1 and the cooling fin 7, a thermal connection is formed via the heat conductive material 10. The heat generated in power conduction in the semiconductor element 3 can be efficiently reduced.

Although the present disclosure is described above in detail, the foregoing description is in all aspects illustrative and does not restrict the disclosure. It is therefore understood that numerous modifications not exemplified can be devised.

In the present disclosure, each embodiment can be arbitrarily combined, or each embodiment can be appropriately varied or omitted.

### EXPLANATION OF REFERENCE SIGNS

1 base plate, 1a fitting part, 2 insulating substrate, 2a insulating layer, 2b front surface conductive pattern, 2c back surface conductive pattern, 3 semiconductor element, 4 case, 5 lead, 6 sealing material, 7 cooling fin, 7a flat plate part, 7b fin part, 7c mounting surface, 7d heat radiation surface, 7e concave part. 8 bonding part, 9a bonding material, 9b bonding material, 9c bonding material, 10 heat conductive material, 17 cooling fin, 18 bonding part, 28 bonding part, 31 base plate, 38 bonding part, 101 to 105 semiconductor device.

1. A method of manufacturing a semiconductor device, comprising:
a step of preparing a base plate holding a semiconductor element; and
a step of attaching a cooling fin to a back surface of the base plate, wherein
the step of attaching the cooling fin includes a step of forming a bonding part in which the base plate and the cooling fin are bonded by welding, and
the bonding part is formed in a region other than a region immediately below the semiconductor element.

2. The method of manufacturing the semiconductor device according to claim 1, further comprising:
a step of fixing a case manufactured by insert molding and integrally formed with a lead to the base plate; and
a step of bonding the lead to an upper surface of the semiconductor element, wherein
the step of preparing the base plate includes:
a step of bonding an insulating substrate with a conductive pattern on front and back side to a front surface of the base plate; and
a step of bonding the semiconductor element to a surface of the insulating substrate, and
the step of attaching the cooling fin is executed after the step of bonding the insulating substrate to the base plate, the step of bonding the semiconductor element to the insulating substrate, and the step of bonding the lead to the semiconductor element.

3. The method of manufacturing the semiconductor device according to claim 1, wherein
the step of forming the bonding part includes forming the bonding part by laser welding.

4. The method of manufacturing the semiconductor device according to claim 1, wherein
the cooling fin includes a flat plate part and a fin part,
the flat plate part includes a mounting surface facing the back surface of the base plate, a heat radiation surface which is a surface on a side opposite to the mounting surface and to which the fin part is provided, and a concave part provided to the heat radiation surface,
the concave part is disposed in a part of the heat radiation surface in which the fin part is not provided,
the step of forming the bonding part includes forming the bonding part in the concave part, and
a top part of a welding mark in the bonding part is lower than the heat radiation surface around the concave part.

5. The method of manufacturing the semiconductor device according to claim 1, wherein
the step of preparing the base plate includes:
a step of bonding an insulating substrate to a front surface of the base plate; and
a step of bonding the semiconductor element to the insulating substrate,
the insulating substrate includes an insulating layer, a front surface conductive pattern bonded to the semiconductor element and provided to an upper surface of the insulating layer, and a back surface conductive pattern bonded to the base plate and provided to a lower surface of the insulating layer, and
the step of forming the bonding part includes forming the bonding part in a region other than a region immediately below the back surface conductive pattern.

6. The method of manufacturing the semiconductor device according to claim 1, wherein
the base plate includes a fitting part in the back surface of the base plate to which a part of the cooling fin is fitted,
the step of attaching the cooling fin includes a step of fitting the cooling fin to the fitting part, and
the step of forming the bonding part includes bonding a region including a gap between a side surface of the fitting part and a side surface of the cooling fin fitted to the fitting part to form the bonding part.

7. The method of manufacturing the semiconductor device according to claim 1, wherein
the step of attaching the cooling fin includes a step of applying or printing a heat conductive material between the base plate and the cooling fin.

8. A semiconductor device, comprising:
a semiconductor element;
a base plate holding the semiconductor element;
a cooling fin attached to a back surface of the base plate; and
a bonding part bonding the base plate and the cooling fin, wherein
the bonding part is provided in a region other than a region immediately below the semiconductor element.

9. The semiconductor device according to claim 8, wherein
the cooling fin includes a flat plate part and a fin part,
the flat plate part includes a mounting surface facing the back surface of the base plate, a heat radiation surface which is a surface on a side opposite to the mounting surface and to which the fin part is provided, and a concave part provided to the heat radiation surface,
the concave part is disposed in a part of the heat radiation surface in which the fin part is not provided,
the bonding part is provided to the concave part, and
a top part of a welding mark in the bonding part is lower than the heat radiation surface around the concave part.

10. The semiconductor device according to claim 8, further comprising
an insulating substrate including an insulating layer, a front surface conductive pattern bonded to the semiconductor element and provided to an upper surface of the insulating layer, and a back surface conductive pattern bonded to the base plate and provided to a lower surface of the insulating layer, wherein
the bonding part is provided in a region other than a region immediately below the back surface conductive pattern.

11. The semiconductor device according to claim 8, wherein
the base plate includes a fitting part in the back surface of the base plate to which part of the cooling fin is fitted,
the bonding part bonds a region including a gap between a side surface of the fitting part and a side surface of the cooling fin fitted to the fitting part.

12. The semiconductor device according to claim 8, further comprising
a heat conductive material provided between the base plate and the cooling fin.
